(19) United States
(12) Patent Application Publication
(10) Pub. No.: US 2005/0212038 A1
(43) Pub. Date: Sep. 29, 2005

(54) Leakage control in semiconductor apparatus and fabricating method

(75) Inventor: Hideaki Fujiwara, Tsukuba-shi (JP)

Correspondence Address: MCDERMOTT WILL & EMERY LLP, 600 13TH STREET, N.W., WASHINGTON, DC, 20005-3096, US

(73) Assignee: Sanyo Electric Co., Ltd.

(21) Appl. No.: 11/090,009

(22) Filed: Mar. 28, 2005

(30) Foreign Application Priority Data
Mar. 29, 2004 (JP) 2004-095698

(51) Int. Cl. H01L 29/76; H01L 21/336

(52) U.S. Cl. 257/330; 438/259

(57) ABSTRACT

A source region and a drain region spaced apart from each other are provided in a semiconductor substrate separating adjacent devices by shallow trench isolation (STI). The semiconductor substrate between the source region and the drain region is selectively removed so as to form a recess for a gate electrode. A recess for the gate electrode is formed in the recess. The gate electrode is formed in the recess via a gate insulating film and a gate coating. The underside of the gate insulating film is located below the underside of a source extension region and a drain region.

### BACKGROUND OF THE INVENTION

1. Field of the Invention

The present invention relates to a semiconductor apparatus and a method of fabricating the apparatus and, more particularly, to a field-effect transistor with an elevated source/drain structure and a method of fabricating the same.

2. Description of the Related Art

Recently, as the scale of integration of a semiconductor integrated circuit advances, the structure of a MOS field-effect transistor (MOSFET) has become finer in accordance with the scaling rules. As the structure of a MOSFET has become finer, a channel in a MOSFET has become increasingly shorter. In addition, a gate insulating film provided between a gate and a substrate has become increasingly thinner (see, for example, patent document No. 1).

An increasingly finer structure of a MOSFET, however, presents a problem with the stability of MOSFET operation in that punch through caused by reduced channel length in a MOSFET is more likely to occur and a leakage current is more likely to be produced due to a thinner gate insulating film.

Patent document No. 1

Japanese Published Patent Application No. 2000-232221

### SUMMARY OF THE INVENTION

The present invention has been done in view of the aforementioned circumstances and its object is to provide a highly reliable semiconductor apparatus and a method of fabricating such a semiconductor apparatus.

Another and more specific object of the present invention is to provide a semiconductor apparatus in which a leakage current between a gate electrode and a substrate is controlled, and a method of fabricating such a semiconductor apparatus.

The semiconductor apparatus according to one aspect of the present invention comprises: a semiconductor substrate; a source region and a drain region formed in the semiconductor substrate; and a gate electrode provided in a recess formed in the semiconductor substrate between the source region and the drain region, via a gate insulating film, wherein the underside of the gate insulating film is below the underside of each of the source region and the drain region.

In accordance with this aspect, a conductive channel is unlikely to be formed between the source region and the drain region since the gate insulating film presents a barrier. Accordingly, punch through between the source region and the drain region is controlled.

The semiconductor apparatus may further comprise: a source side wall insulating film provided between the source region and the gate electrode; a drain side wall insulating film provided between the drain and the gate electrode; a source extension region formed below the source side wall insulating film and joined with the source region, a drain extension region formed below the drain side wall insulating film and joined with the drain region, wherein the underside of the gate insulating film is located below the underside of each of the source extension region and the drain extension region.

According to this aspect, the gate insulating film presents a barrier in a structure in which extensions are provided in a diffusion region. As a result, a conductive channel is unlikely to be formed between the source extension region and the drain extension region. Accordingly, punch through between the source extension region and the drain extension region is controlled.

The gate insulating film may include hafnium, zirconium or aluminum. The gate insulating film is a high-k insulating film capable of controlling a leakage current between the gate electrode and the semiconductor substrate.

A gate coating formed of a metal or silicide may be provided between the gate insulating film and the gate electrode. With this, the channel potential can be suitably controlled.

The method of fabricating a semiconductor apparatus according to one aspect comprises: forming first and second ion-implanted region spaced apart from each other in a semiconductor substrate; selectively removing a region of the semiconductor substrate bordered by the first ion-implanted region and the second ion-implanted region so as to form a recess; diffusing impurities contained in the first and second ion-implanted regions downward to the position shallower than the depth of the recess; and forming a gate electrode on an etched region of the semiconductor substrate via a gate insulating film.

In accordance with this aspect, a highly reliable semiconductor apparatus in which punch through between the source region and the drain region is controlled can be fabricated.

The method of fabricating a semiconductor apparatus according to another aspect comprises: forming first and second ion-implanted region spaced apart from each other in a semiconductor substrate; selectively removing regions in the semiconductor substrate bordered by the first ion-implanted region and the second ion-implanted region so as to form first and second recesses; forming third and fourth ion-implanted regions at the bottom of the first and second recesses, respectively; embedding an insulator in each of the first and second recesses; forming a recess for a gate electrode by selectively removing a region of the semiconductor substrate bordered by the third ion-implanted region and the fourth ion-implanted region into a level lower than the underside of each of the third ion-implanted region and the fourth ion-implanted region; diffusing impurities contained in the first and second ion-implanted regions downward and causing the first and second ion-implanted regions to be joined with the third and fourth ion-implanted regions, respectively; and forming, via a gate insulating film, a gate electrode in a region of the semiconductor substrate between the third ion-implanted region and the fourth ion-implanted region.

In accordance with this aspect, a highly reliable semiconductor apparatus in which punch through between the source region and the drain region is controlled can be fabricated.

Appropriate combinations of the aforementioned elements are within the scope of the invention sought to be patented in this application.

### BRIEF DESCRIPTION OF THE DRAWINGS

FIG. 1 is a schematic sectional view illustrating the structure of a semiconductor apparatus according to an embodiment of the present invention.

FIG. 2 is a schematic plan view illustrating the structure of the semiconductor apparatus according to the embodiment.

FIG. 3 is a sectional view illustrating a process of fabricating the semiconductor apparatus according to the embodiment.

FIG. 4 is another sectional view illustrating a process of fabricating the semiconductor apparatus according to the embodiment.

FIG. 5 is another sectional view illustrating a process of fabricating the semiconductor apparatus according to the embodiment.

FIG. 6 is another sectional view illustrating a process of fabricating the semiconductor apparatus according to the embodiment.

FIG. 7 is another sectional view illustrating a process of fabricating the semiconductor apparatus according to the embodiment.

FIG. 8 is another sectional view illustrating a process of fabricating the semiconductor apparatus according to the embodiment.

FIG. 9 is another sectional view illustrating a process of fabricating the semiconductor apparatus according to the embodiment.

FIG. 10 is another sectional view illustrating a process of fabricating the semiconductor apparatus according to the embodiment.

FIG. 11 is another sectional view illustrating a process of fabricating the semiconductor apparatus according to the embodiment.

FIG. 12 is another sectional view illustrating a process of fabricating the semiconductor apparatus according to the embodiment.

FIG. 13 is a schematic sectional view illustrating the structure of a semiconductor apparatus according to an alternative embodiment of the present invention.

FIG. 14 is a schematic plan view illustrating the structure of the semiconductor apparatus according to the alternative embodiment.

### DETAILED DESCRIPTION OF THE INVENTION

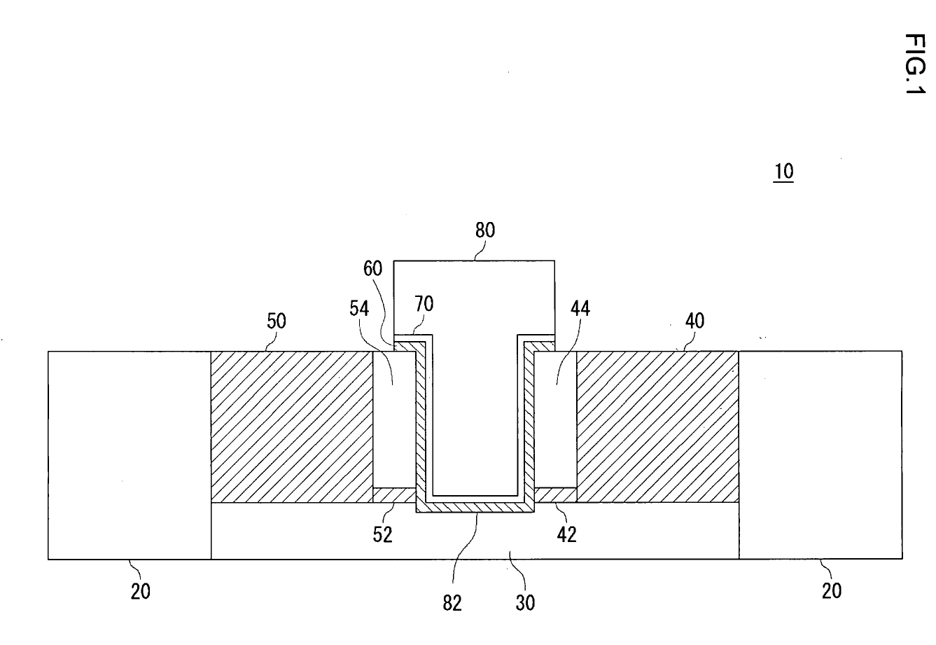

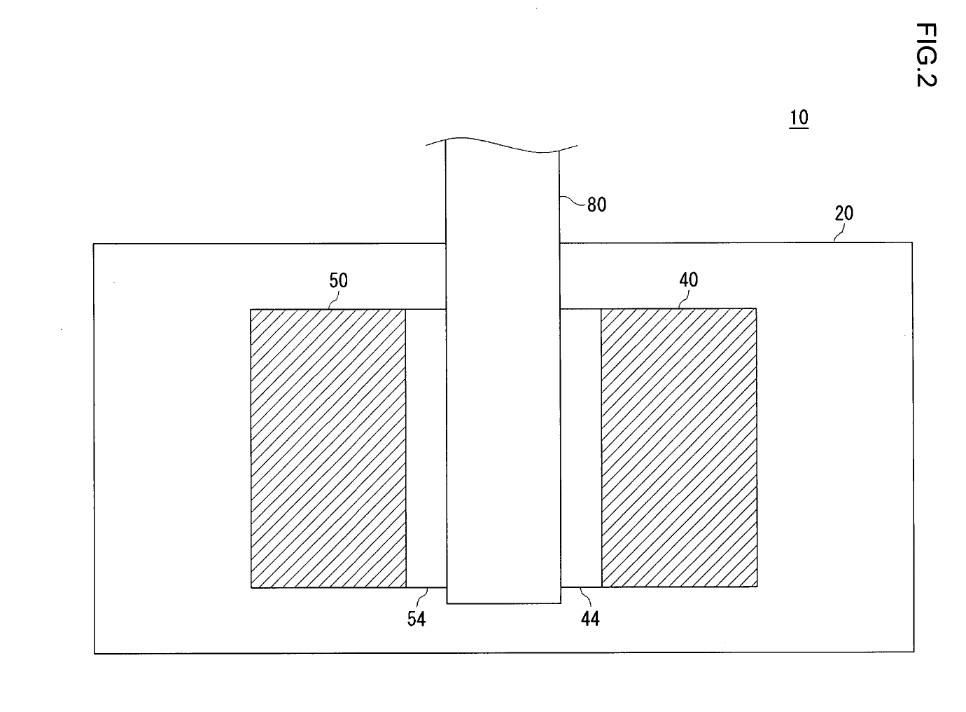

The semiconductor apparatus and the method of fabricating the apparatus according to the present invention is illustrated below in greater detail by referring to the drawings. FIG. 1 is a schematic sectional view illustrating the structure of a semiconductor apparatus 10 according to an embodiment of the present invention. FIG. 2 is a schematic plan view illustrating the structure of the semiconductor apparatus 10 according to the embodiment. In a semiconductor substrate 30, a shallow trench isolation (STI) 20 separates adjacent devices according to a known method. A source region 40 and a drain region 50 are provided in the trench-isolated semiconductor substrate 30 with a separation between the regions. An area of the semiconductor substrate 30 between the source region 40 and the drain region 50 is selectively removed and a recess for a gate electrode is formed in the removed area. A gate electrode 80 is formed in a recess 82 for the gate electrode via a gate insulating film 60. A gate coating 70 is provided as appropriate between the gate insulating film 60 and the gate electrode 80. The gate coating 70 corrects the work function of the gate electrode 80.

As described, the semiconductor apparatus 10 is provided with a recessed structure in which a region for the gate electrode 80 is lodged in the semiconductor substrate 30. The semiconductor apparatus 10 is also provided with an elevated source/drain structure in which the source region 40 and the drain region 50 are elevated with respect to the Si region of the semiconductor substrate 30.

In this embodiment, an SI (110) substrate from a wafer with a plane direction of (110) is used. In the Si(110) substrate, the (111) plane is normal to the wafer surface and is suitably used to form, by etching, a recessed structure the wall of which is normal to the wafer surface.

The lower end of the source region 40 and the lower end of the drain region 50 are joined with a source extension region 42 and a drain extension region 52, respectively. The ends of the source extension region 42 and the drain extension region 52 facing the gate electrode 80 are blocked by the gate insulating film 60.

The side walls of the source region 40, the drain region 50 and the gate electrode 80 are perpendicular to the principal surface of the semiconductor substrate 30.

In a region surrounded by the side wall of the source region 40, the source extension region 42 and the gate insulating film 60, a source side wall insulating film 44 is embedded along the perpendicular side wall of the source region 40. In a region surrounded by the side wall of the drain region 50, the drain extension region 52 and the gate insulating film 60, a drain side wall insulating film 54 spaced apart from the source side wall insulating film 44 is embedded along the perpendicular side wall of the drain region 50.

The gate insulating film 60 may be formed of silicon oxide. Preferably, the gate insulating film 60 is a high-k insulating film that contains hafnium, zirconium or aluminum. With this, a leakage current between the gate electrode 80 and the semiconductor substrate 30 is effectively controlled.

Since the underside of gate insulating film 60 is located below the underside of each of the source region 40, the source extension region 42, the drain region 50 and the drain extension region 52, a conductive channel is not likely to be formed between the source region 40 and the drain region 50. Accordingly, punch through between the source region 40 and the drain region 50 is controlled.

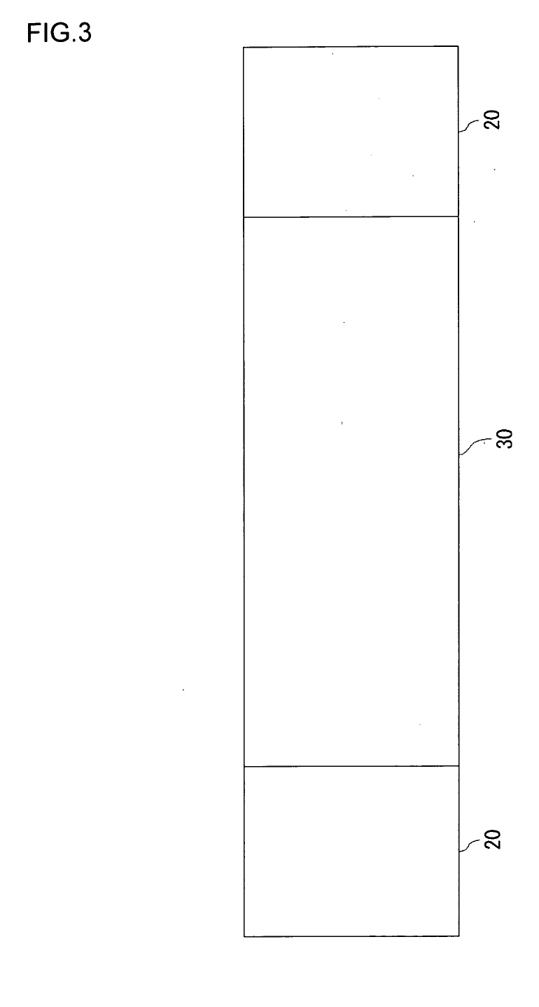

FIGS. 3 through 12 illustrate processes of fabricating the semiconductor apparatus according to the embodiment. As illustrated in FIG. 3, trench isolation is applied to the semiconductor substrate 30 using the shallow trench isolation (STI) 20. In this embodiment, an Si(110) substrate is used for the semiconductor substrate 30. In place of the STI 20 or in addition to the STI 20, a channel stopper that contains a high content of impurities of the same conductivity type as the semiconductor substrate 30 may be used.

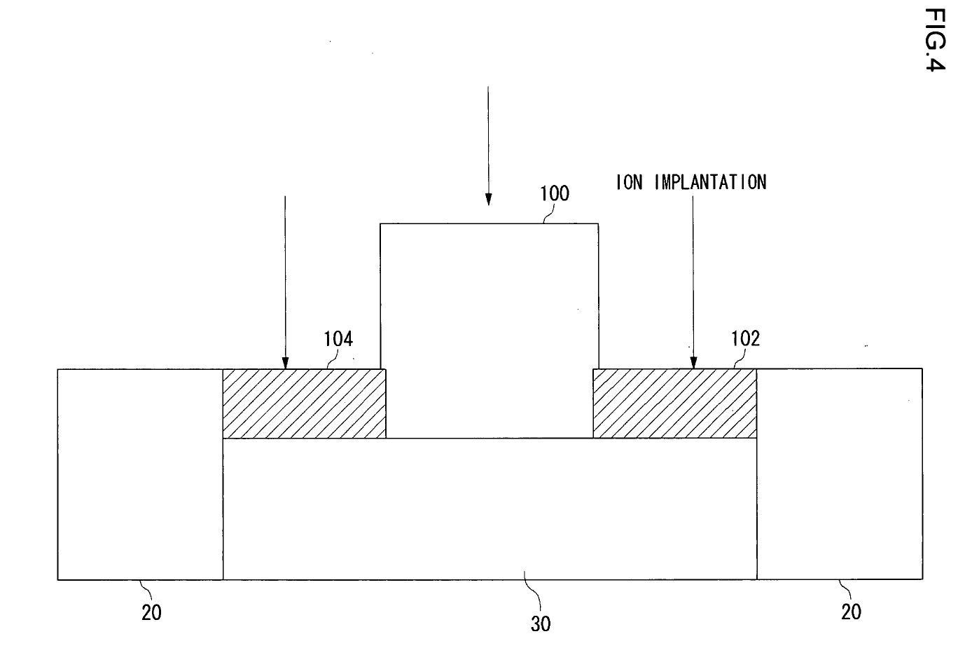

Subsequently, as illustrate in FIG. 4, a low-temperature silicon oxide film, i.e. an LTO film, is formed on the semiconductor substrate 30. A typical thickness of the LTO film 100 is 200 nm and the length thereof in the source-to-drain direction of FIG. 4 (hereinafter, simply referred to as the length L) is 200 nm. Subsequently, donor impurities such as Arsenic (As) and phosphorous (P) and acceptor impurities such as boron (B) and aluminum (Al) are implanted as ions into the semiconductor substrate 30, using the LTO film 100 as a mask, so as to form an ion-implanted region 102 and an ion implanted region 104. A typical dose of impurities is 3×10¹⁵ cm⁻².

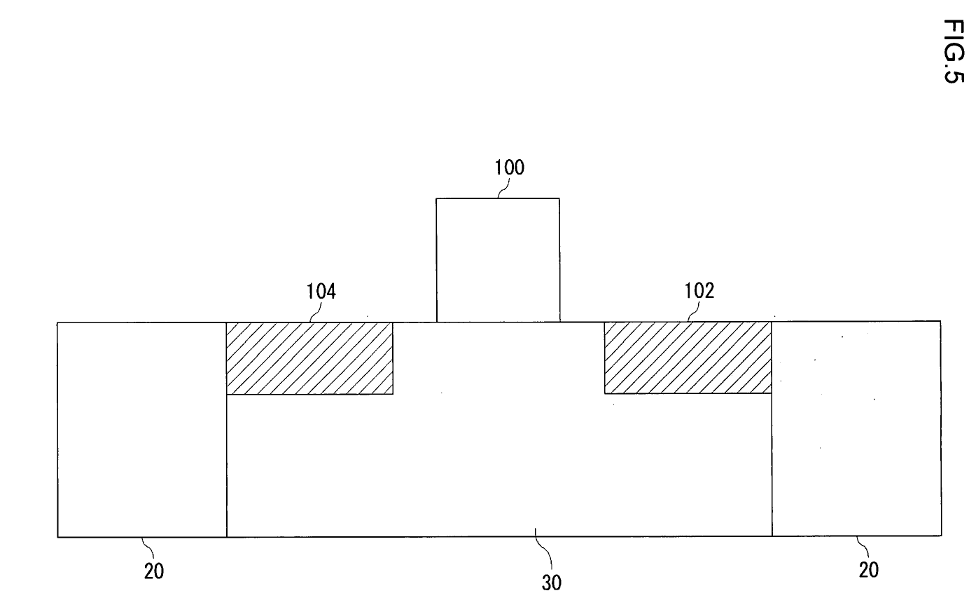

Subsequently, as illustrated in FIG. 5, the semiconductor substrate 30 is immersed in a diluted hydrofluoric acid (DHF) solution so that the LTO film 100 is isotropically wet-etched. Given that the thickness of the LTO film 100 is 200 nm, the length L is 200 nm and an etching rate is approximately 25 nm/min, a typical depth of etching is 70 nm. With this, the LTO film 100 is slimmed down to a thickness of 130 nm and a length L of 60 nm.

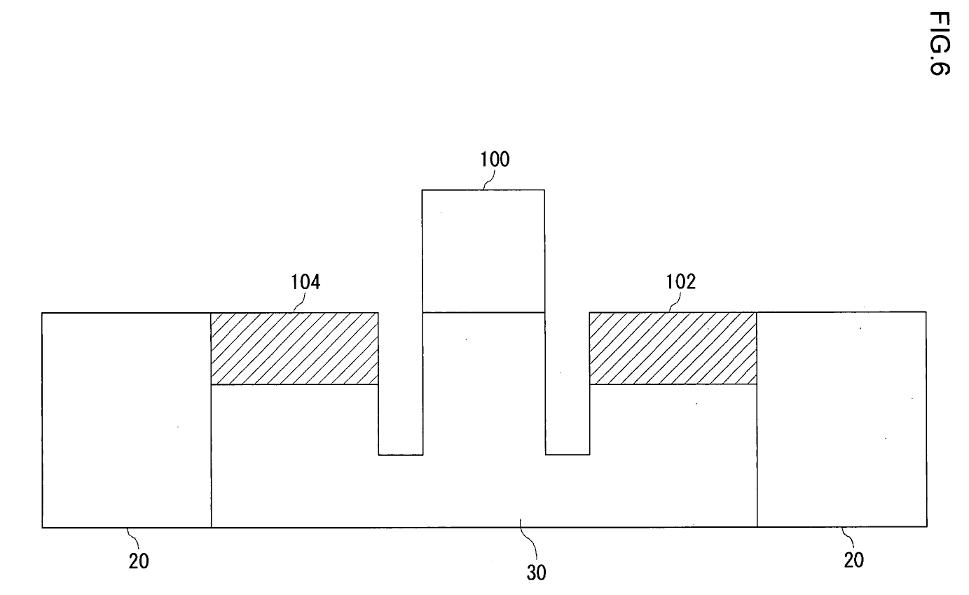

Subsequently, as illustrated in FIG. 6, the semiconductor substrate 30 is wet-etched by an alkali etchant such as tetramethylammonium hydroxide (TMAH) at a temperature of 50° C. or below. The rate of etching the Si(110) substrate by an alkali etchant in the (111) plane direction normal to the wafer surface is approximately 100 times slower than that of the other plane directions. The region of the semiconductor substrate 30 rendered amorphous by ion implantation is not etched. Therefore, the semiconductor substrate 30 is anisotropically etched, using, as a mask, the ion-implanted region 102 and the ion-implanted region 104 which are rendered amorphous by ion implantation, as well as the LTO film 100 slimmed down by the DHF isotropic etching. With this, the semiconductor substrate 30 is worked so that the (111) plane normal to the wafer surface remains unetched. As a result, a pair of recesses are formed in regions respectively bounded by the ion-implanted region 102 and the ion-implanted region 104. Typically, the depth of each of a pair of the pair of recesses is 100 nm.

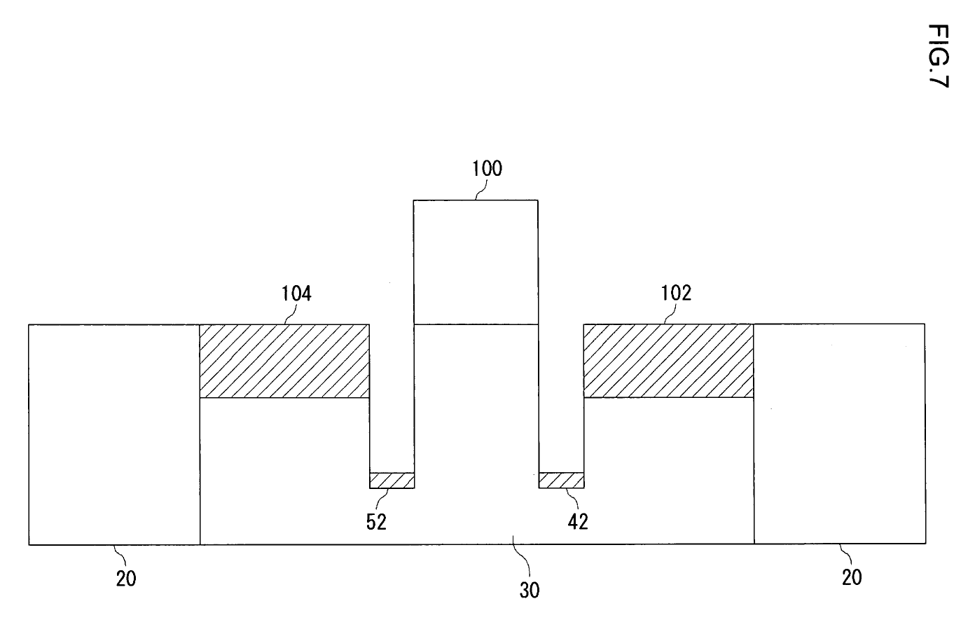

Subsequently, as illustrated in FIG. 7, a chemical oxide film is formed by a hydrogen peroxide/hydrochloric acid solution (SC-2) cleaning at the bottom of each of the recesses formed in the semiconductor substrate 30 by anisotropic etching. Subsequently, the chemical oxide film is removed by implantation of ions of the same conductivity type as the impurities used to form the ion-implanted region 102 and the ion-implanted region 104. By ion implantation at the bottom of the recesses in the semiconductor substrate 30, the source extension region 42 and the drain extension region 52 are formed. A typical dose of impurities implanted in each of the source extension region 42 and the drain extension region 52 is 1×10¹⁵ cm⁻² at an implantation energy of 3 keV. A typical thickness of each of the source extension region 42 and the drain extension region 52 in the direction of depth is 10 nm.

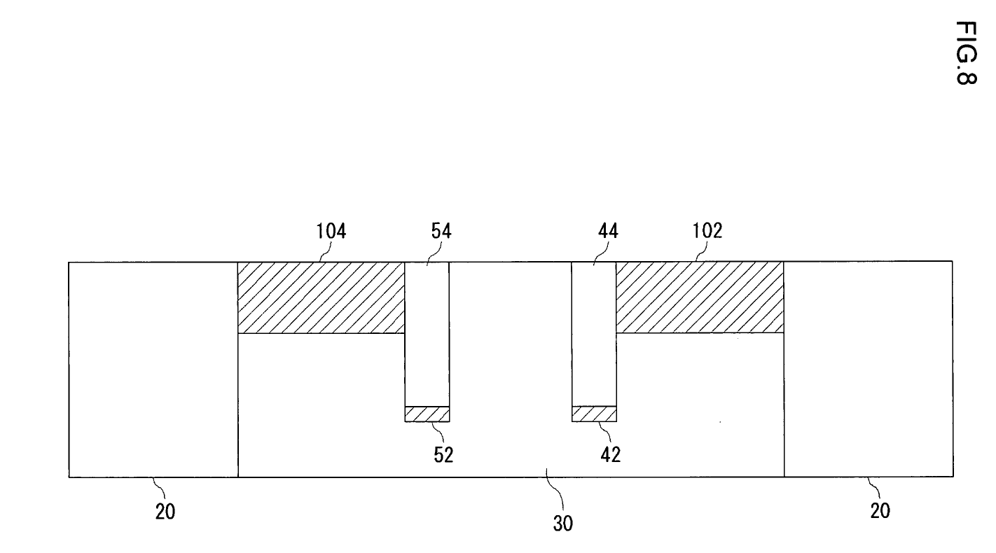

Subsequently, as illustrated in FIG. 8, an oxide such as a silicon oxide film is embedded in the recesses in the semiconductor substrate 30 by a high-density plasma process, so as to form the source side wall insulating film 44 and the drain side wall insulating film 54. Subsequently, the LTO film 100 on the semiconductor substrate 30 is removed by chemical and mechanical polishing so as to expose the Si surface on which a gate is formed.

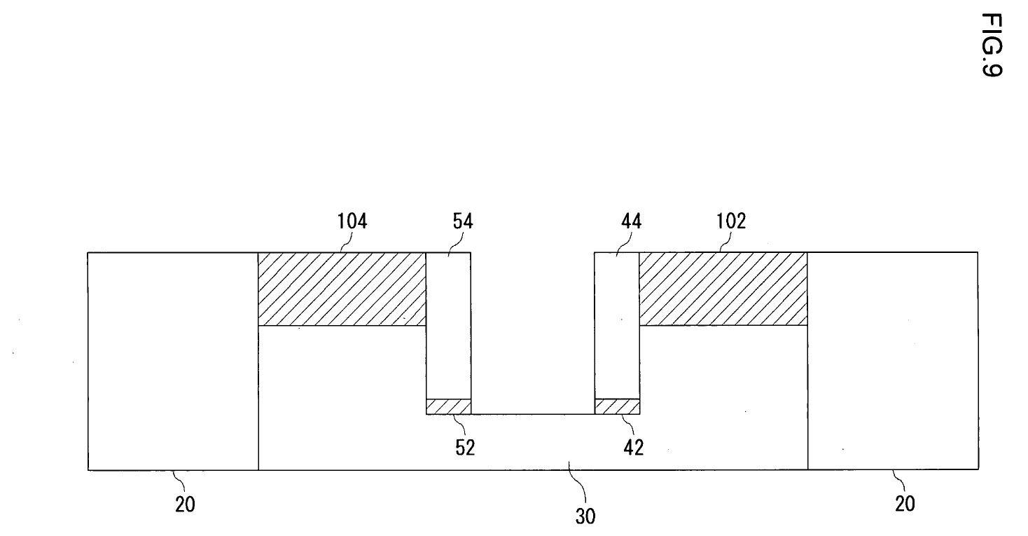

Subsequently, as illustrated in FIG. 9, the semiconductor substrate 30 is wet-etched by an alkali etchant such as TMAH. The depth of etching is greater than the depth of the pair of recesses formed in the process illustrated in FIG. 6. For example, given the depth of the aforementioned pair of recesses is 100 nm, the depth of wet-etching into the semiconductor substrate 30 is typically 110 nm.

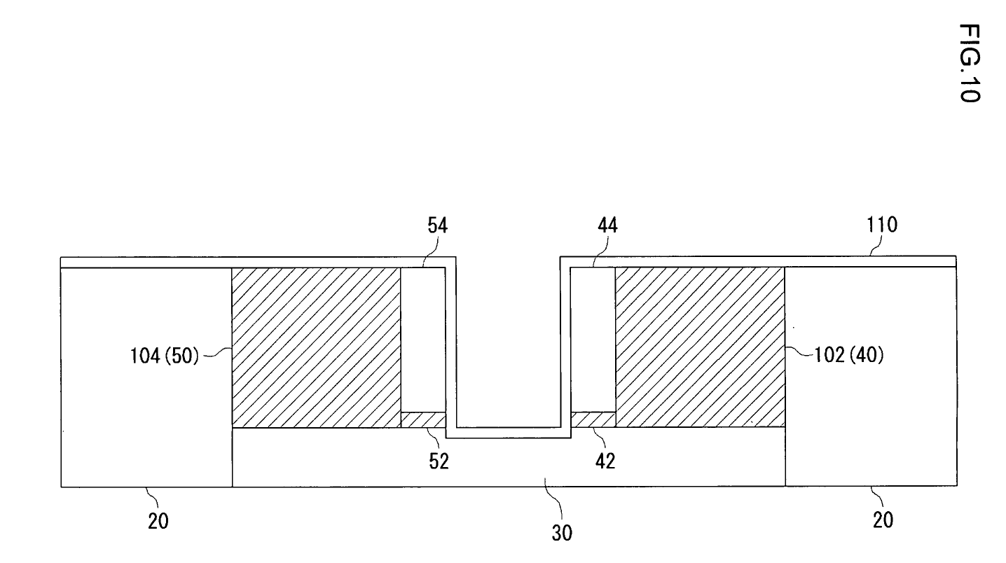

Subsequently, as illustrated in FIG. 10, a sacrificial oxide film 110 such as a silicon oxide film is formed on the exposed surface of the semiconductor substrate 30. Impurities contained in the ion-implanted region 102 and the ion-implanted region 104 are then diffused downward by activation annealing. Diffusion in the ion-implanted region 102 and the ion-implanted region 104 is controlled by a condition in which activation annealing is done such that the underside of each of the ion-implanted region 102 and the ion-implanted region 104 is aligned with the underside of each of the source extension region 42 and the drain extension region 52. The ion-implanted region 102 is joined with the source extension region 42. The ion-implanted region 104 is joined with the drain extension region 52. Subsequently, the sacrifice oxide film 110 is removed by fluoric acid. As a result of diffusion, the ion-implanted region 102 and the ion-implanted region 104 are rendered the source region 40 and the drain region 50, respectively.

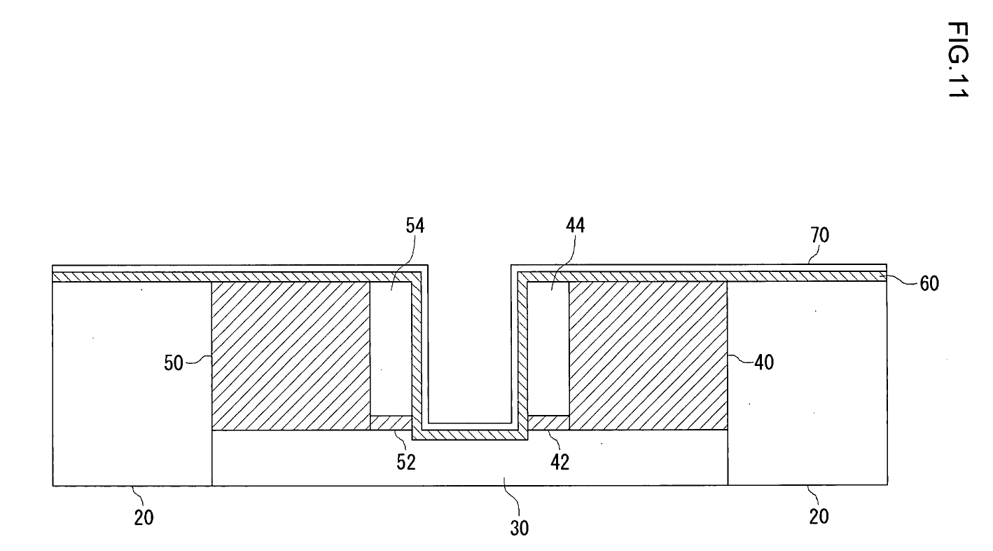

Subsequently, as illustrated in FIG. 11, the gate insulating film 60 is formed on the exposed surface of each of the semiconductor substrate 30, the source extension region 42, the drain extension region 52, the source side wall insulating film 44, the drain side wall insulating film 54, the source region 40, the drain region 50 and the STI 20. Atomic layer deposition (ALD) or chemical vapor deposition (CVD) may suitably be used to form the gate insulating film 60. The high-k insulating film used for the gate insulating film 60 may be formed of hafnium oxide, zirconium oxide, aluminum oxide, hafnium silicate, zirconium silicate or aluminum silicate by way of examples. A typical thickness of the gate insulating film 60 is 5 nm.

Subsequently, the gate coating 70 for correcting the work function of the gate electrode is formed on the gate insulating film 60 depending on the type of gate electrode. The gate coating film 70 may be a metal film formed of titanium (Ti) or tantalum (Ta), or a silicide film. With this, the channel potential is suitably controlled.

The materials used for the gate coating 70 may be tungsten silicide, molybdenum silicide, titanium silicide, cobalt silicide or nickel silicide by way of examples.

The silicide film may be formed directly on the gate insulating film 60. Alternatively, the region on the gate insulating film 60 underlying the gate may be patterned with a poly-Si layer. Subsequently, a salicide may be formed by building a metal such as Ti for formation of a silicide on the poly-Si layer and then applying a thermal process to induce a silicide reaction.

After the silicide film is formed or in the process of forming the silicide film, a metal such as Ti that attracts Si into the metal during the silicide reaction may be provided on the silicide film. This helps full-scale silicidation reaching the interface with the gate insulating film 60 to occur in the silicide film.

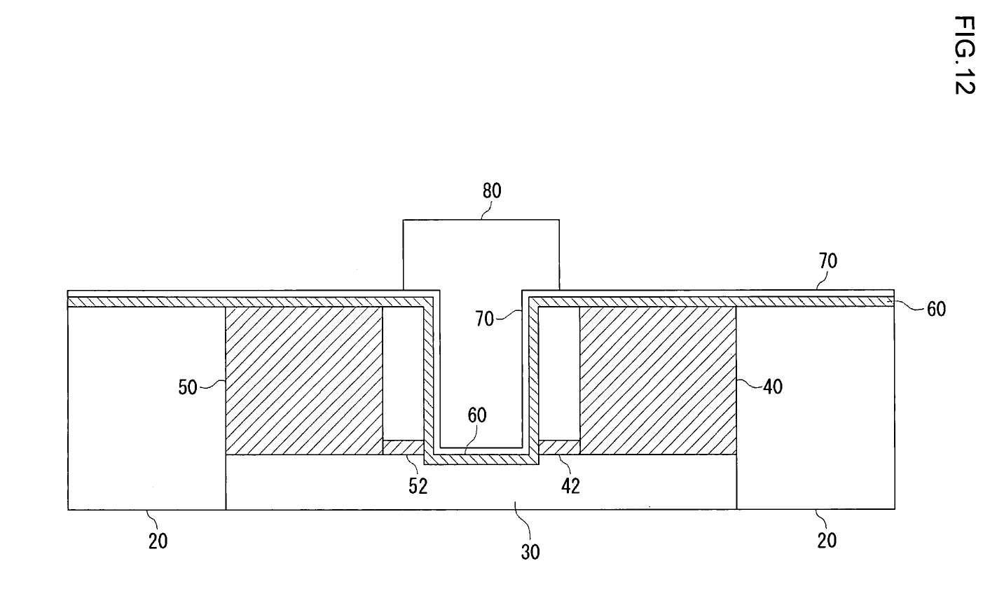

Subsequently, as illustrated in FIG. 12, the gate electrode 80 formed of tungsten or the like is formed in the region for gate formation. The gate electrode 80 may be elevated above the top face of each of the STI 20, the source region 40 and the drain region 50. Finally, the gate insulating film 60 and the gate coating 70 are selectively etched to remove unnecessary portions so that the semiconductor apparatus 10 illustrated in FIG. 1 is obtained.

As described, the gate-last process, in which the gate insulating film 60, the gate coating 70 and the gate electrode 80 are formed after the source region 40 and the drain region 50 are formed, is employed to fabricate the semiconductor apparatus 10. As a benefit from this, the gate insulating film 60, which largely affects the operating properties of the semiconductor apparatus 10, is prevented from being heated by activation annealing or the like. Accordingly, degradation in properties of the semiconductor apparatus 10 such as leakage characteristics and mobility is controlled.

In a field-effect semiconductor with an elevated source/drain structure, the junction depth in the source region 40 and in the drain region 50 is practically zero. According to the inventive semiconductor, a leakage current between the source and the drain is controlled without forming an extension of the source and the drain using a special impurity profile control technology. This is achieved by ensuring that a region of the semiconductor substrate 30 between the source extension region 42 and the drain extension region 52 is lower than the underside of each of the source region 40, the source extension region 42, the drain region 50 and the drain extension region 52.

Although the present invention has been described by way of exemplary embodiments, it should be understood that many changes and substitutions may further be made by those skilled in the art without departing from the scope of the present invention.

For example, an n-type MOSFET and a p-type MOSFET separated by the STI 20 may be formed. In this case, in the ion-implantation process of FIG. 4 and FIG. 7d, donors are implanted in a region in which the n-type MOSFET is formed, and acceptors are implanted in a region in which the p-type MOSFET is formed. In the gate electrode formation process illustrated in FIG. 11, a high-k insulating film is formed in regions in which the n-type MOSFET and the p-type MOSFET are formed. After forming a poly-Si layer on the high-k insulating film, a metal for coating the gate of the n-MOSFET is deposited. In a region in which the p-type MOSFET is formed, a metal for coating the gate of the p-type MOSFET is deposited after removing the metal for coating the gate of the n-MOSFET by etching. Thereafter, a silicide reaction is induced in the regions in which the n-MOSFET and the p-type MOSFET are formed.

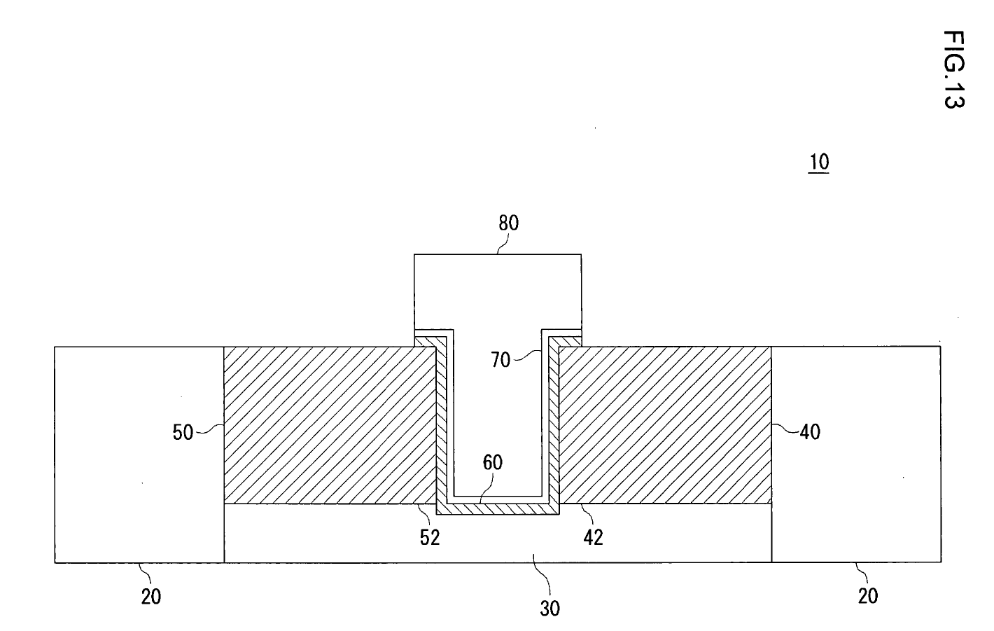

Further, as illustrated in FIG. 13, the processes illustrated in FIG. 5 through FIG. 7 may be omitted, resulting in a structure in which the source extension region 42, the source side wall insulating film 44, the drain extension region 52 and the drain side wall insulating film 54 are not provided.

Since the underside of the gate insulating film 60 is still located below the underside of each of the source region 40 and the drain region 50, a conductive channel is unlikely to be formed between the source region 40 and the drain region 50. Thereby, punch through between the source region 40 and the drain region 50 is controlled.

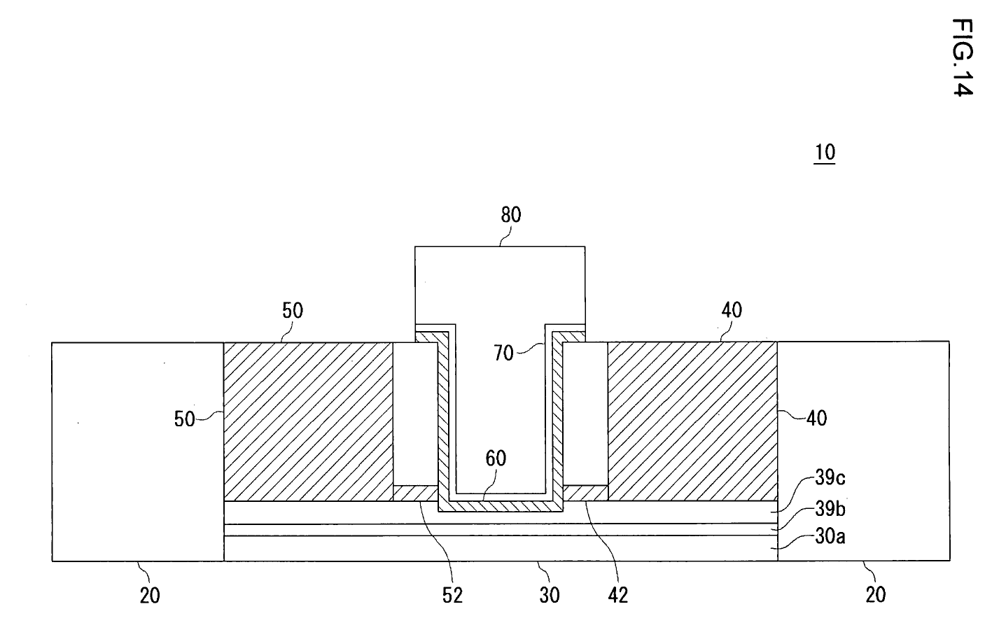

Further, as illustrated in FIG. 14, a silicon on insulator (SOI) substrate may be used as the semiconductor substrate 30. With this, complete trench isolation is applied to the semiconductor substrate 30. Accordingly, parasitic capacitance in the semiconductor substrate 30 is reduced and the operating speed is increased.

1. A semiconductor apparatus comprising:
a semiconductor substrate;
a source region and a drain region formed in the semiconductor substrate; and
a gate electrode provided in a recess formed in the semiconductor substrate between the source region and the drain region, via a gate insulating film, wherein
the underside of the gate insulating film is below the underside of each of the source region and the drain region.

2. The semiconductor apparatus according to claim 1, further comprising:
a source side wall insulating film provided between the source region and the gate electrode;
a drain side wall insulating film provided between the drain and the gate electrode;
a source extension region formed below the source side wall insulating film and joined with the source region; and
a drain extension region formed below the drain side wall insulating film and joined with the drain region, wherein
the underside of the gate insulating film is located below the underside of each of the source extension region and the drain extension region.

3. The semiconductor apparatus according to claim 1, wherein the gate insulating film comprises hafnium, zirconium or aluminum.

4. The semiconductor apparatus according to claim 2, wherein the gate insulating film comprises hafnium, zirconium or aluminum.

5. The semiconductor apparatus according to claim 3, wherein a gate coating formed of a metal or a silicide is provided between the gate insulating film and the gate electrode.

6. The semiconductor apparatus according to claim 4, wherein a gate coating formed of a metal or a silicide is provided between the gate insulating film and the gate electrode.

7. A method of fabricating a semiconductor apparatus comprising:
forming first and second ion-implanted region spaced apart from each other in a semiconductor substrate;
selectively removing a region of the semiconductor substrate bordered by the first ion-implanted region and the second ion-implanted region so as to form a recess;
diffusing impurities contained in the first and second ion-implanted regions downward to the position shallower than the depth of the recess; and
forming a gate electrode on an etched region of the semiconductor substrate via a gate insulating film.

8. A method of fabricating a semiconductor apparatus comprising:
forming first and second ion-implanted region spaced apart from each other in a semiconductor substrate;
selectively removing regions in the semiconductor substrate bordered by the first ion-implanted region and the second ion-implanted region so as to form first and second recesses;
forming third and fourth ion-implanted regions at the bottom of the first and second recesses, respectively;
embedding an insulator in each of the first and second recesses;
forming a recess for a gate electrode by selectively removing a region of the semiconductor substrate bordered by the third ion-implanted region and the fourth ion-implanted region into a level lower than the underside of each of the third ion-implanted region and the fourth ion-implanted region;
diffusing impurities contained in the first and second ion-implanted regions downward and causing the first and second ion-implanted regions to be joined with the third and fourth ion-implanted regions, respectively; and
forming, via a gate insulating film, a gate electrode in a region of the semiconductor substrate between the third ion-implanted region and the fourth ion-implanted region.
